(19) United States
(12) Patent Application Publication
(10) Pub. No.: US 2015/0255513 A1
(43) Pub. Date: Sep. 10, 2015

(54) SEMICONDUCTOR MEMORY DEVICE

(71) Applicant: Kabushiki Kaisha Toshiba, Minato-ku (JP)

(72) Inventors: Yoshinori NAKAKUBO, Yokkaichi-shi (JP); Shigeki Kobayashi, Kuwana-shi (JP); Takeshi Yamaguchi, Yokkaichi-shi (JP); Hiroyuki Ode, Yokkaichi-shi (JP); Masaki Yamato, Yokkaichi-shi (JP)

(73) Assignee: Kabushiki Kaisha Toshiba, Minato-ku (JP)

(21) Appl. No.: 14/306,441

(22) Filed: Jun. 17, 2014

Related U.S. Application Data
(60) Provisional application No. 61/947,735, filed on Mar. 4, 2014.

(51) Int. Cl. H01L 27/24; G11C 13/00; H01L 45/00

(52) U.S. Cl. CPC H01L 27/2481; H01L 45/1253; H01L 45/146; G11C 13/0097

(57) ABSTRACT

In accordance with an embodiment, a semiconductor memory device includes a substrate, first and second wirings on the substrate across each other, and a storage element at an intersection of the first and second wirings between the first and second wirings. The storage element includes first and second electrodes having first and second materials, respectively, a first film having a first dielectric constant, and a second film having a second dielectric constant lower than the first dielectric constant. The first film is formed on the first electrode. The second electrode is formed on the first film. The second film is disposed between the second electrode and the first film. An energy difference between a vacuum level and a Fermi level of the second material is equal to or more than an energy difference between the vacuum level and a Fermi level of the first material.

### CROSS REFERENCE TO RELATED APPLICATIONS

This application is based upon and claims the benefit of U.S. provisional Application No. 61/947,735, filed on Mar. 4, 2014, the entire contents of which are incorporated herein by reference.

### FIELD

Embodiments described herein relate generally to a semiconductor memory device.

### BACKGROUND

If write operations are repeated in a memory cell of a resistive random access memory (hereinafter briefly referred to as a “ReRAM”), the characteristics of the memory cell may deteriorate. One of the causes is the deterioration of a resistance change film as an RW film resulting from the load of a high voltage on the resistance change film during a switching operation.

### BRIEF DESCRIPTION OF THE DRAWINGS

In the accompanying drawings:

FIG. 1 is a block diagram showing an example of a general configuration of a semiconductor memory device according to Embodiment 1;

FIG. 2 shows an example of a partial perspective view of an example of a memory cell array included in the semiconductor memory device shown in FIG. 1;

FIG. 3 is an example of a perspective view of one memory cell viewed in an arrow direction through the line II-II in FIG. 2;

FIG. 4 is an example of a front view showing an example of a storage element shown in FIG. 3;

FIG. 5 is a graph showing an example of an oxygen profile of an SiOₓ film included in the storage element shown in FIG. 3;

FIG. 6 is a diagram illustrating an example of the control of an electrode potential by a pulse generator shown in FIG. 1;

FIG. 7 is a diagram showing an example of an energy band of the storage element shown in FIG. 3;

FIG. 8 to FIG. 22 show examples of diagrams of other examples of the storage element shown in FIG. 3;

FIG. 23 is an example of a perspective view showing a stack structure of another example of the memory cell array included in the semiconductor memory device shown in FIG. 1;

FIG. 24 is an example of a sectional view of FIG. 23; and

FIG. 25 is an example of a partially enlarged view of FIG. 24.

### DETAILED DESCRIPTION

In accordance with an embodiment, a semiconductor memory device includes a substrate, first and second wirings and a storage element. The first and second wirings are disposed on the substrate across each other. The storage element is disposed at an intersection of the first and second wirings between the first and second wirings. The storage element includes a first electrode having a first material, a first film having a first dielectric constant, a second electrode having a second material, and a second film having a second dielectric constant lower than the first dielectric constant. The first electrode is electrically connected to the first wiring. The first film is formed on the first electrode. The second electrode is formed on the first film and is electrically connected to the second wiring. The second film is disposed between the second electrode and the first film. An energy difference between a vacuum level and a Fermi level of the second material is equal to or more than an energy difference between the vacuum level and a Fermi level of the first material.

Embodiments will now be explained with reference to the accompanying drawings. Like components are provided with like reference signs throughout the drawings and repeated descriptions thereof are appropriately omitted.

In the following explanation, a “set operation” means that a resistance change material in a high-resistance state shifts to a low-resistance state, and a “reset operation” means that the resistance change material in the low-resistance state shifts to the high-resistance state. Moreover, in the following explanation, a “write operation” means that the resistance change material performs the set operation or the reset operation, that is, data is written into a memory cell, and a “read operation” means that the resistance state of the resistance change material is detected, that is, data in the memory cell is read. The set operation and the reset operation when performed in the memory cell by the application of voltages of different polarities may be referred to as “bipolar operations”.

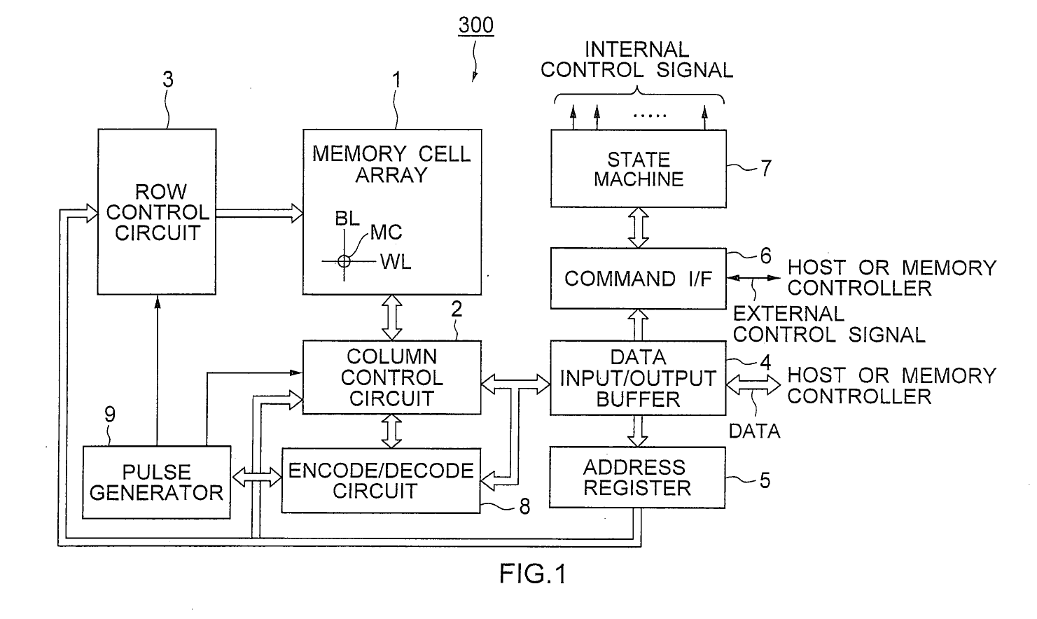

FIG. 1 is a block diagram showing a general configuration of a semiconductor memory device according to Embodiment 1.

A semiconductor memory device 300 according to the present example includes a memory cell array 1 which has a plurality of bit lines BL, a plurality of word lines WL intersecting with the bit lines BL, and a plurality of memory cells MC provided at the intersections of the bit lines BL and the word lines WL. The memory cell MC is configured by a ReRAM in the present embodiment.

A column control circuit 2 which controls the bit lines BL of the memory cell array 1 and which performs a write operation and a read operation for the memory cell MC is provided at a position adjacent to the memory cell array 1 in a bit line BL direction.

A row control circuit 3 which selects the word line WL of the memory cell array 1 and which applies a voltage necessary for the write operation and the read operation for the memory cell MC is provided at a position adjacent to the memory cell array 1 in a word line WL direction.

A data input/output buffer 4 is connected to an external host or a memory controller via an I/O line, and receives write data, outputs read data, and receives address data and command data. The data input/output buffer 4 sends the received write data to the column control circuit 2, and receives the data read from the column control circuit 2 and then outputs the data to the outside. The address supplied to the data input/output buffer 4 from the outside is sent to the column control circuit 2 and the row control circuit 3 via an address register 5. The command supplied to the data input/output buffer 4 from the host or the like is sent to a command interface 6.

In response to an external control signal from the host or the like, the command interface 6 judges whether the data input to the data input/output buffer 4 is write data, a command, or an address. If the data is, for example, a command, the command interface 6 transfers the command to a state machine 7 as a receipt command signal.

The state machine 7 manages the whole semiconductor memory device 300, and performs the write operation, the read operation, and data input/output management in response to a command from the host or the like.

The data input to the data input/output buffer 4 from the host or the like is transferred to an encode/decode circuit 8, and an output signal of the encode/decode circuit 8 is input to a pulse generator 9. The pulse generator 9 outputs a write pulse of a predetermined voltage and a predetermined timing in response to the input signal. The pulse generated in and output from the pulse generator 9 is transferred to a given wiring selected by the column control circuit 2 and the row control circuit 3.

In the present embodiment, the pulse generator 9 corresponds to, for example, a control circuit.

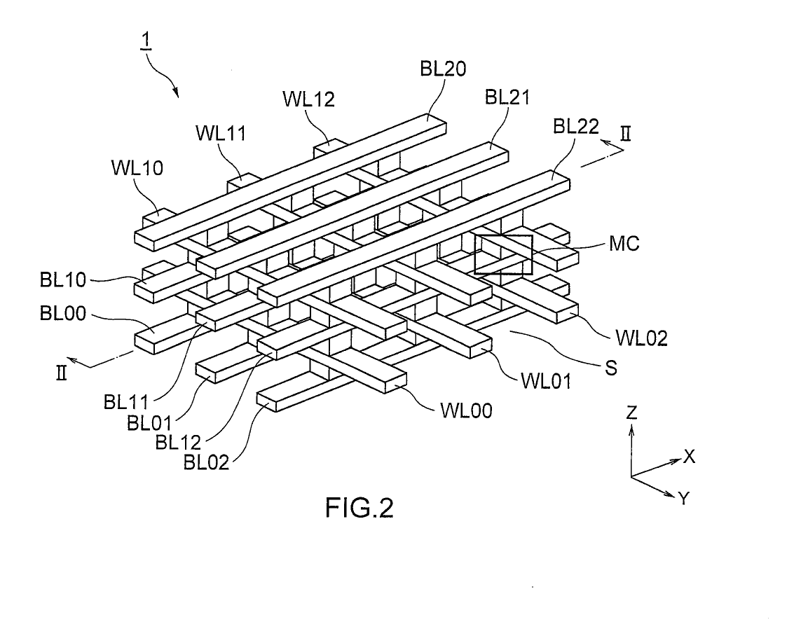

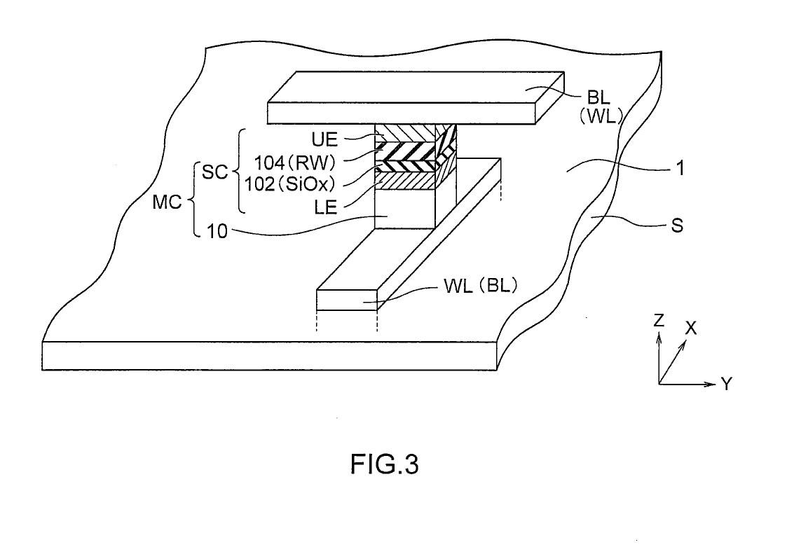

FIG. 2 shows an example of a partial perspective view of an example of the memory cell array 1. FIG. 3 is an example of a perspective view of one memory cell viewed in an arrow direction through the line II-II in FIG. 2.

As shown in FIG. 2, a plurality of bit lines BL0 to BL2 are provided in parallel on the main surface of a substrate S, and a plurality of word lines WL0 to WL2 are provided in parallel across the bit lines. As shown in FIG. 2 and FIG. 3, a stack of a current control element 10 and a resistance change type storage element SC is disposed as the memory cell MC between each of the bit lines BL0 to BL2 and each of the word lines WL0 to WL2 at each intersection.

The word lines WL0 to WL2 and the bit lines BL0 to BL2 are preferably made of heat-resistant materials having low resistance values. For example, as such materials, tungsten (W), tungsten silicide (WSi), nickel silicide (NiSi), and cobalt silicide (CoSi) can be used. In the present embodiment, the word lines WL0 to WL2 correspond to, for example, a first wiring, and the bit lines BL0 to BL2 correspond to, for example, a second wiring.

As shown in FIG. 3, the memory cell MC according to the present embodiment includes the current control element 10 and the resistance change type storage element SC. The current control element 10 and the resistance change type storage element SC are connected in series to each other. The word line WL (or the bit line BL), the current control element 10, the resistance change type storage element SC, and the bit line BL (or the word line WL) are stacked and formed in a columnar shape in a direction perpendicular to the main surface of the substrate S from the lower layer to the upper layer, that is, in a Z-direction in FIG. 3.

Although a silicon wafer is used as the substrate S in the present embodiment, the substrate S is not limited to such a semiconductor substrate. It is also possible to use an insulating substrate such as a glass substrate or a ceramic substrate.

The current control element 10 is configured by, for example, a PIN diode.

In the present embodiment, the resistance change type storage element SC is configured by, a lower electrode LE, a low-dielectric-constant film 102, a resistance change film RW made of a resistance change material 104, and an upper electrode UE.

The lower electrode LE is electrically connected to the word line WL (or the bit line BL) via the current control element 10, and the upper electrode UE is electrically connected to the bit line BL (or the word line WL). In the present embodiment, the upper electrode UE corresponds to, for example, a first electrode, and the lower electrode LE corresponds to, for example, a second electrode. Moreover, in the present embodiment, the resistance change material 104 (RW) corresponds to, for example, a first film, and the low-dielectric-constant film 102 corresponds to, for example, a second film.

The upper electrode UE and the lower electrode LE can be each made of not only a metallic nitride film such as titanium nitride (TiN) or tantalum nitride (TaN) and tungsten (W) but also a polysilicon film doped with an impurity.

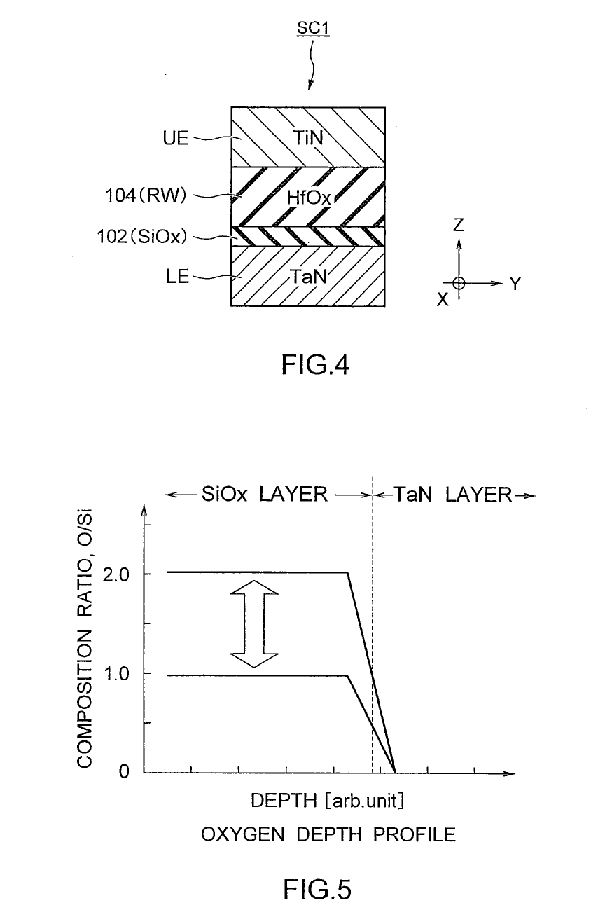

A more specific configuration of the resistance change type storage element SC is described with reference to FIG. 4. In a resistance change type storage element SC1 according to an example shown in FIG. 4, the upper electrode UE is made of a titanium nitride (TiN) film, and the lower electrode LE is made of a tantalum nitride (TaN) film. These metallic nitride films can be formed by, for example, chemical vapor deposition (CVD).

The resistance change material 104 (RW) is a material which is capable of shifting to at least two resistance states: the low-resistance state shifts and the high-resistance state. When a voltage equal to or more than a given voltage is applied, the resistance change material 104 (RW) in the high-resistance state shifts to the low-resistance state (set operation). On the other hand, when a current equal to or more than a given current runs, the resistance change material 104 (RW) in the low-resistance state shifts to the high-resistance state (set operation). The resistance change material 104 (RW) can be configured by a thin film made of one of materials selected from the group consisting of titanium oxide (TiO₂), spinel zinc manganese oxide (ZnMn₂O₄), nickel oxide (NiO), strontium zirconate (SrZrO₃), PCMO (Pr0.7Ca0.3MnO₃), and carbon, in addition to hafnium oxide (HfOₓ). In the present embodiment, hafnium oxide (HfOₓ) is described by way of example.

The low-dielectric-constant material layer 102 is a film made of a material lower in dielectric constant than the resistance change material 104 (RW), and is made of silicon oxide (SiOₓ (∈=3.9)) having a dielectric constant lower than the dielectric constant ∈(>20) of hafnium oxide (HfOₓ) in the present embodiment. Here, as shown in FIG. 5, the composition ratio (O/Si) of oxygen and silicon in silicon oxide (SiOₓ) at a certain distance from the lower electrode LE ranges from 1.0 to 2.0 (1≦x≦2).

Stages of the configurations described above are repetitively formed in a direction normal to a main surface 1 of the substrate S, that is, in a Z-direction. Consequently, the semiconductor memory device shown in FIG. 2 constitutes a memory device having what is known as a planar cross-point type three-dimensional structure.

According to the semiconductor memory device in the present embodiment, the low-dielectric-constant material layer 102 is located between the lower electrode LE and the resistance change film 104 (RW). Therefore, the low-dielectric-constant material layer 102 is applied to a strong electric field, whereas the resistance change film 104 (RW) is applied to a relatively weak electric field when the pulse generator 9 applies a voltage so that the lower electrode LE is higher in voltage than the upper electrode UE in the set operation. As a result, it is possible to reduce the concentration of the high electric field in the resistance change film 104 (RW).

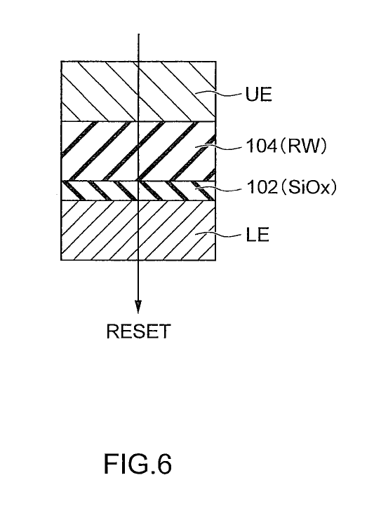

As shown in FIG. 6, in the reset operation, the pulse generator 9 controls the voltage so that electrons run from the low-dielectric-constant material layer 102 to the resistance change film 104 (RW), that is, so that the voltage of the lower electrode LE is lower than the voltage of the upper electrode UE. As a result, the resistance change material 104 (RW) in the low-resistance state shifts to the high-resistance state. This electrode potential control enables efficient switching at the interface where the low-dielectric-constant material layer 102 is in contact with the resistance change film 104 (RW).

If materials having different work functions are used to constitute the upper electrode UE and the lower electrode LE, more efficient set/reset operations can be provided.

For example, in the structure of the resistance change type storage element SC1 shown in FIG. 4, the upper electrode UE is made of titanium nitride (TiN), whereas the lower electrode LE is made of tantalum nitride (TaN), so that the work functions of the metallic materials are different from each other.

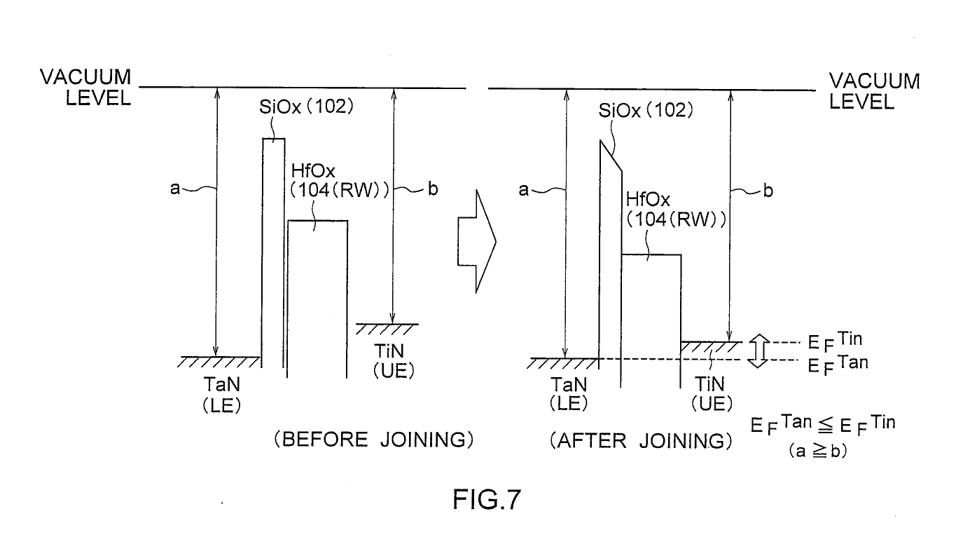

FIG. 7 shows an example of an energy band of the resistance change type storage element SC1.

The left diagram in FIG. 7 is an energy band diagram before joining (each layer is out of contact and independent). In this case, an energy difference a between a vacuum level and a Fermi level of the lower electrode LE (TaN) and an energy difference b between the vacuum level and a Fermi level of the upper electrode UE (TiN) have a relation of a>b.

The right diagram in FIG. 7 is an example of an energy band in a thermal equilibrium state when the materials having the above relation are joined. In the energy band diagram in the thermal equilibrium state after joining, the relation between the energy difference “a” and the energy difference “b” is a≧b. The strength of the electric field concentrating in the low-dielectric-constant material layer 102 inserted between the lower electrode LE and the resistance change film 104 (RW) can be controlled up to a target value by selecting constituent materials of the upper electrode UE and the lower electrode LE so as to have the above relation.

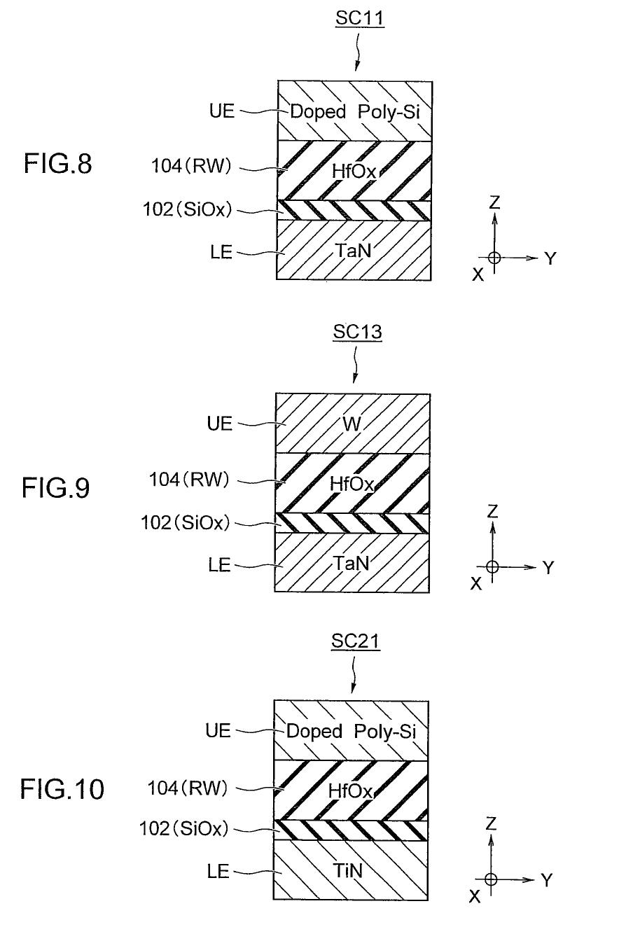

As examples of the combination of electrode materials having the relation: energy difference “a”≧energy difference b, combinations shown in FIG. 8 to FIG. 14 are adaptable in addition to the combination of the upper electrode UE of titanium nitride (TiN) and the lower electrode LE of tantalum nitride (TaN) shown in FIG. 4.

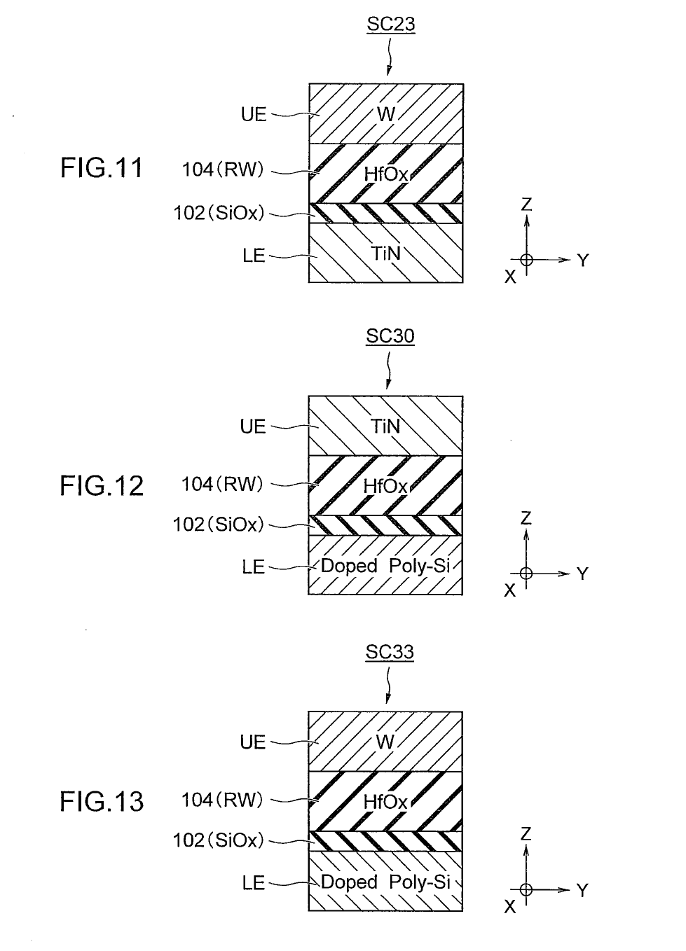

In examples of resistance change type storage elements SC11 and SC13 shown in FIG. 8 and FIG. 9, the upper electrode UE shown in FIG. 4 is made of polysilicon doped with an impurity (doped poly-Si) and tungsten (W), respectively. In examples of resistance change type storage elements SC21 and SC23 shown in FIG. 10 and FIG. 11, the lower electrode LE is made of titanium nitride (TiN) in the configurations respectively shown in FIG. 8 and FIG. 9, respectively.

In an example of a resistance change type storage element SC30 shown in FIG. 12, the upper and lower electrode materials in the configuration shown in FIG. 10 are inverted, so that the upper electrode UE is made of titanium nitride (TiN), and the lower electrode LE is made of polysilicon doped with an impurity (doped poly-Si).

In an example of a resistance change type storage element SC33 shown in FIG. 13, the upper electrode UE is made of tungsten (W) in the configuration shown in FIG. 12.

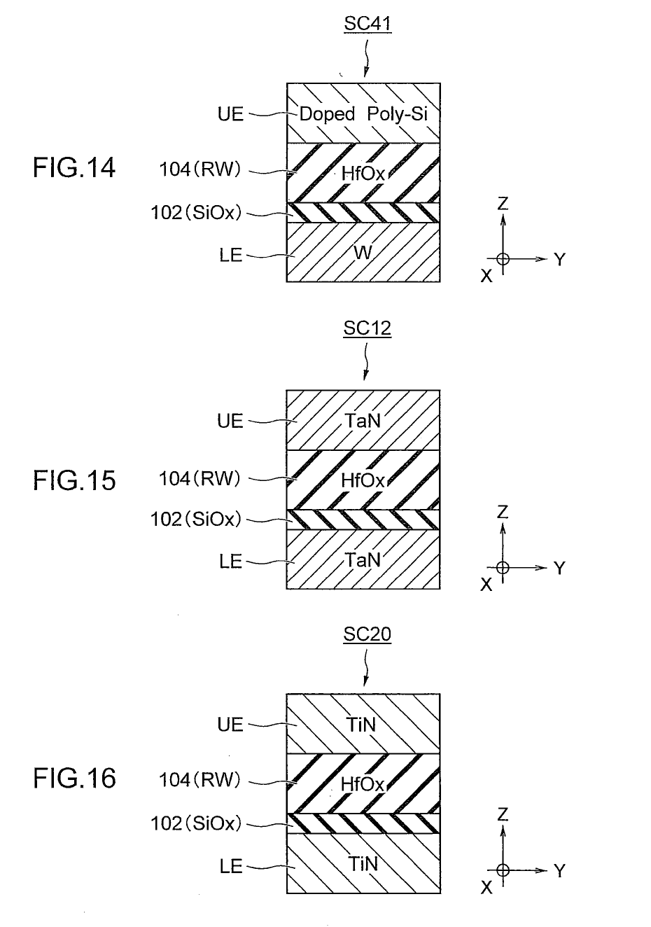

Furthermore, in an example of a resistance change type storage element SC41 shown in FIG. 14, the upper and lower electrode materials in the configuration shown in FIG. 13 are inverted, so that the upper electrode UE is made of polysilicon doped with an impurity (doped poly-Si), and the lower electrode LE is made of tungsten (W). Thus, according to the present embodiment, a more efficient switching operation can be provided by selecting the combination of the materials of the upper electrode UE and the lower electrode LE. Consequently, a semiconductor memory device lower in current and voltage is provided.

The configuration of the resistance change type storage element SC is not limited to the examples shown in FIG. 4 and FIG. 8 to FIG. 14, and can be embodied in various forms.

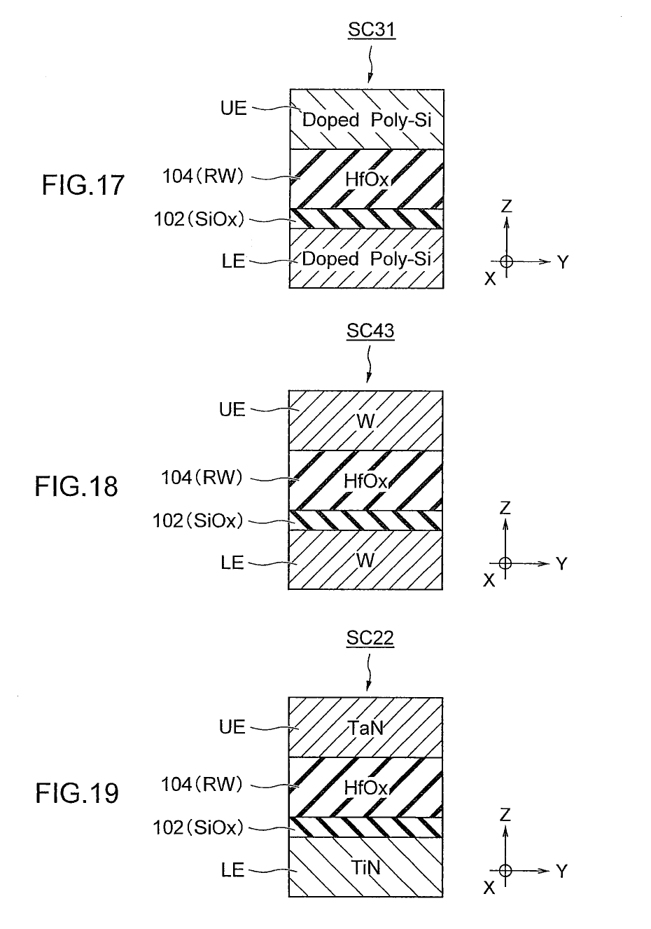

For example, the same material can be used in the upper electrode UE and the lower electrode LE as shown in FIG. 15 to FIG. 18.

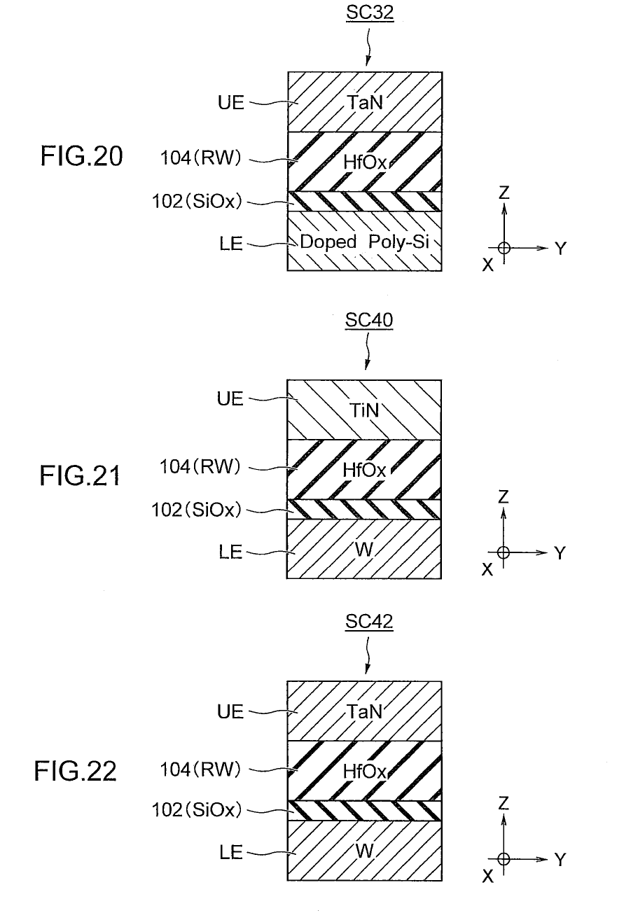

As the electrode materials, it is possible to use tantalum nitride (TaN), titanium nitride (TiN), polysilicon doped with an impurity (doped poly-Si), and tungsten (W). There are combinations of these materials shown in FIG. 19 to FIG. 22 in addition to the above-mentioned combinations.

Furthermore, it will be appreciated that not only the materials described above but also other metals can be used.

The above-described configuration examples of the resistance change type storage element SC can be suitably inverted in the Z-direction and used.

The above-described semiconductor memory device according to Embodiment 1 includes the low-dielectric-constant material layer 102 which reduces the concentration of the electric field in the resistance change film 104 (RW), and includes the pulse generator 9 which controls the potentials of the word lines WL and the bit lines BL in such a manner that the current flows from the resistance change film 104 (RW) to the low-dielectric-constant material layer 102. Therefore, it is possible to suppress resistance to deterioration caused by the repetition of the set operation and the reset operation in the resistance change type storage element SC. Consequently, a semiconductor memory device having satisfactory data retention characteristics is provided.

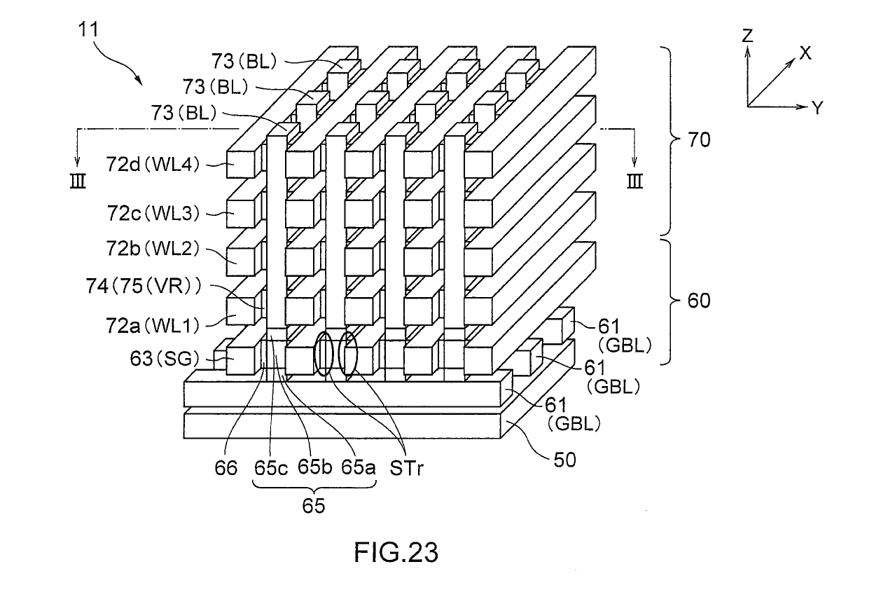

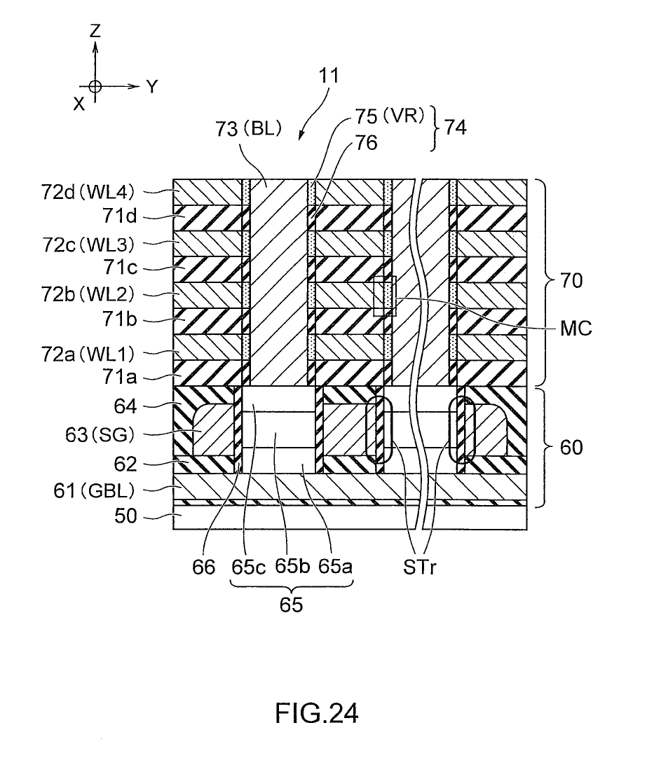

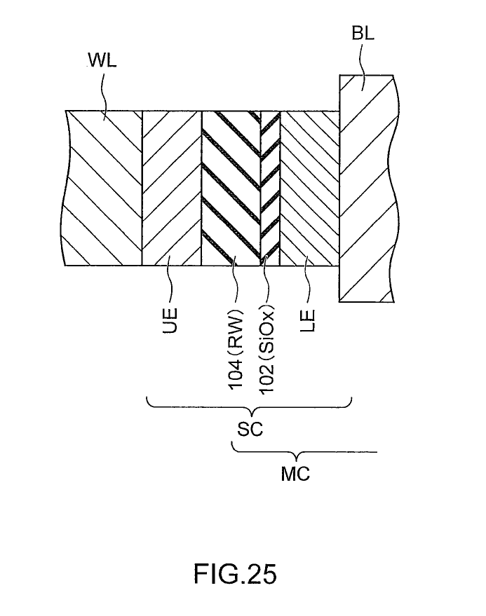

The resistance change type storage element SC according to the present embodiment is not limited to the planar cross type memory cell array 1 shown in FIG. 2, and is also applicable to, for example, memory cell arrays shown in FIG. 23 to FIG. 25. FIG. 23 is an example of a perspective view of a memory cell array 11 in this example. FIG. 24 is an example of a sectional view taken along the line in FIG. 23. FIG. 25 is an example of an enlarged view of a part indicated by the sign MC in FIG. 24. In FIG. 23, interlayer insulating films are not shown.

As shown in FIG. 23 and FIG. 24, the memory cell array 11 has a select transistor layer 60 and a memory layer 70 that are stacked on a substrate 50. A plurality of select transistors STr are arranged in the select transistor layer 60, and a plurality of memory cells MC are arranged in the memory layer 70.

As shown in FIG. 23 and FIG. 24, the select transistor layer 60 has an electric conducting layer 61, an interlayer insulating layer 62, an electric conducting layer 63, and an interlayer insulating layer 64 that are stacked in the Z-direction perpendicular to the main plane of the substrate 50. The electric conducting layer 61 functions as a global bit line GBL, and the electric conducting layer 63 functions as a select gate line SG and a gate of a select transistor STr.

The electric conducting layers 61 are arranged with a predetermined pitch in an X-direction parallel to the main plane of the substrate 50, and extend in a Y-direction. The interlayer insulating layer 62 covers the upper surface of the electric conducting layer 61 as shown in FIG. 24. The electric conducting layers 63 are arranged with a predetermined pitch in the Y-direction, and extend in the X-direction. The interlayer insulating layer 64 covers the side surface and upper surface of the interlayer insulating layer 64 as shown in FIG. 24. The electric conducting layers 61 and 63 are made of, for example, polysilicon. The interlayer insulating layers 62 and 64 are made of, for example, silicon oxide (SiO₂).

As shown in FIG. 23 and FIG. 24, the select transistor layer 60 also has a columnar semiconductor layer 65 and a gate insulating layer 66. The columnar semiconductor layer 65 functions as a body (channel) of the select transistor STr, and the gate insulating layer 66 functions as a gate insulating film of the select transistor STr.

The columnar semiconductor layer 65 is arranged in matrix form in the X- and Y-directions, and extends in a columnar shape in the Z-direction. The columnar semiconductor layer 65 is in contact with the upper surface of the electric conducting layer 61, and is in contact with the side surface at a Y-direction end of the electric conducting layer 63 via the gate insulating layer 66. The columnar semiconductor layer 65 has, for example, an N⁺-type semiconductor layer 65a, a P⁺-type semiconductor layer 65b, and an N⁺-type semiconductor layer 65c that are stacked.

As shown in FIG. 23 and FIG. 24, the N⁺-type semiconductor layer 65a has the side surface at its Y-direction end in contact with the interlayer insulating layer 62 via the gate insulating layer 66, and the P⁺-type semiconductor layer 65b has the side surface at its Y-direction end in contact with the side surface of the electric conducting layer 63 via the gate insulating layer 66. The N⁺-type semiconductor layer 65c has the side surface at its Y-direction end in contact with the interlayer insulating layer 64 via the gate insulating layer 66. The N⁺-type semiconductor layers 65a and 65c are made of polysilicon doped with an N⁺-type impurity. The P⁺-type semiconductor layer 65b is made of polysilicon doped with a P⁺-type impurity. The gate insulating layer 66 is made of, for example, silicon oxide (SiO₂).

As shown in FIG. 23 and FIG. 24, the memory layer 70 has interlayer insulating layers 71a to 71d and electric conducting layers 72a to 72d that are alternately stacked in the Z-direction. The electric conducting layers 72a to 72d function as word lines WL1 to WL4.

The interlayer insulating layers 71a to 71d are made of, for example, silicon oxide (SiO₂), and the electric conducting layers 72a to 72d are made of, for example, polysilicon.

As shown in FIG. 23 and FIG. 24, the memory layer 70 also has a columnar electric conducting layer 73 and a sidewall layer 74.

The electric conducting layer 73 is arranged in matrix form in the X- and Y-directions, is in contact with the upper surface of the columnar semiconductor layer 65, and extends in a columnar shape in the Z-direction together with the columnar semiconductor layer 65. The electric conducting layer 73 functions as a bit line BL. The electric conducting layer 73 is made of, for example, polysilicon.

The sidewall layer 74 is provided on the side surface at the Y-direction end of the electric conducting layer 73. As shown in FIG. 24, the sidewall layer 74 has a variable resistance layer 75 and an insulating layer 76. The variable resistance layer 75 functions as a variable resistance element VR.

The variable resistance layer 75 (VR) is provided between the electric conducting layer 73 and the side surfaces at the Y-direction ends of the electric conducting layers 72a to 72d. As shown in FIG. 25, the variable resistance layer 75 (VR) has, for example, the same configuration as the resistance change type storage element SC shown in FIG. 4. As shown in FIG. 25, the variable resistance layer 75 (VR) also has the lower electrode LE disposed on the bit line BL side, and the upper electrode UE disposed on the word line WL side.

The variable resistance layer 75 (VR) in this example also includes the low-dielectric-constant material layer 102 which lessens the concentration of the electric field in the resistance change film 104 (RW). The variable resistance layer 75 (VR) in this example also has the potentials of the word lines WL and the bit lines BL controlled by the pulse generator 9 (see FIG. 1) so that the current runs from the resistance change film 104 (RW) to the low-dielectric-constant material layer 102. Therefore, resistance to deterioration caused by the repetition of the set operation and the reset operation in the variable resistance layer 75 (VR) is improved. Consequently, a semiconductor memory device having satisfactory data retention characteristics is provided.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, in the embodiment described above by way of example, the low-dielectric-constant material layer 102 is inserted between the lower electrode LE and the resistance change material 104 (RW). However, this is not a limitation. The low-dielectric-constant material layer 102 may be disposed between the upper electrode UE and the resistance change material 104 (RW), or the low-dielectric-constant material layers 102 may be disposed between the respective electrodes and the resistance change material 104 (RW).

The accompanying claims and their equivalents are intended to cover such forms or modifications as would fall within the scope and spirit of the inventions.

1. A semiconductor memory device comprising:
a substrate;
first and second wirings disposed on the substrate across each other; and
a storage element disposed at an intersection of the first and second wirings between the first and second wirings,
the storage element comprising
a first electrode electrically connected to the first wiring and comprising a first material,
a first film formed on the first electrode, which comprises a first dielectric constant,
a second electrode formed on the first film, which is electrically connected to the second wiring and comprises a second material, and
a second film disposed between the second electrode and the first film, which comprises a second dielectric constant lower than the first dielectric constant,
wherein an energy difference between a vacuum level and a Fermi level of the second material is equal to or more than an energy difference between the vacuum level and a Fermi level of the first material.

2. The device of claim 1,
wherein the low-dielectric-constant material is a covalent insulator.

3. The device of claim 2,
wherein the low-dielectric-constant material is SiOₓ.

4. The device of claim 3,
wherein x satisfies a relation 1≦x≦2.

5. The device of claim 1, further comprising
a control circuit configured to control voltages to be applied to the first wiring and the second wiring in such a manner that a current flows from the first film to the second film during a reset operation.

6. The device of claim 1,
wherein the first material comprises one of materials selected from the group consisting of titanium nitride (TiN), tantalum nitride (TaN), polysilicon doped with an impurity, and tungsten (W).

7. The device of claim 1,
wherein the second material is tantalum nitride (TaN).

8. The device of claim 1,
wherein the second film is in contact with the first film.

9. A semiconductor memory device comprising:
a substrate;
first and second wirings disposed on the substrate across each other; and
a storage element disposed at the intersection of the first and second wirings between the first and second wirings,
the storage element comprising
a first electrode electrically connected to the first wiring,
a second electrode electrically connected to the second wiring,
a first film disposed between the first electrode and the second electrode, and
SiOₓ layer exclusively disposed between the second electrode and the first film,
wherein the material of the second electrode comprises tantalum nitride (TaN).

10. The device of claim 9,
wherein the first film comprises HfO.

11. The device of claim 9,
wherein the first material comprises one of materials selected from the group consisting of titanium nitride (TiN), tantalum nitride (TaN), polysilicon doped with an impurity, and tungsten (W).

12. The device of claim 9,
wherein x satisfies a relation 1≦x≦2.

13. The device of claim 9, further comprising
a control circuit configured to control voltages to be applied to the first wiring and the second wiring in such a manner that a current flows from the first film to the second film in a reset operation.

14. The device of claim 9,
wherein the second film is in contact with the first film.
